(19) United States
(12) Patent Application Publication
(10) Pub. No.: US 2009/0189232 A1
(43) Pub. Date: Jul. 30, 2009

(54) Methods and apparatuses providing color filter patterns arranged to reduce the effect of crosstalk in image signals

(75) Inventors: Amnon Silverstein, Palo Alto, CA (US); David Pope, Fremont, CA (US)

Correspondence Address: DICKSTEIN SHAPIRO LLP, 1825 EYE STREET NW, Washington, DC, 20006-5403, US

(73) Assignee: MICRON TECHNOLOGY, INC.

(21) Appl. No.: 12/010,620

(22) Filed: Jan. 28, 2008

(51) Int. Cl. H01L 31/0232

(52) U.S. Cl. 257/432; 257/E31.127

(57) ABSTRACT

Methods and apparatuses providing color filter patterns arranged to reduce cross talk in image signals. The apparatuses include an array of pixels, each pixel having an associated color filter, arranged such that cross-talk is distributed among pixel signals of each color of the color filters.

### FIELD OF THE INVENTION

The embodiments described herein relate generally to imaging devices and, more specifically, to methods and apparatuses employed in such devices providing color filter patterns arranged to reduce the effect of crosstalk in image signals.

### BACKGROUND OF THE INVENTION

Solid state imaging devices, including charge coupled devices (CCD), complementary metal oxide semiconductor (CMOS) imaging devices, and others, have been used in photo imaging applications. A solid state imaging device circuit includes a focal plane array of pixel cells or pixels as an imaging sensor, each cell including a photosensor, which may be a photogate, photoconductor, a photodiode, or other photosensor having a doped region for accumulating photo-generated charge.

Ideally, the digital images created by a solid state imaging device are exact duplications of the light image projected upon the device pixel array. That is, for a flat-field image, all of the imaging pixel signals should have the same signal value. However, various noise sources can affect individual pixel outputs and thus distort the resulting digital image. As pixel arrays increase in size and pixels decrease in size to obtain higher resolution in a smaller imaging area, the physical non-uniformity of the arrays becomes more prominent. One issue occurring in imaging sensors with small pixel size, such as, for example, smaller than 1.75 microns, is crosstalk. Crosstalk occurs when an imaging pixel signal is affected by other signals in the imaging device, such as, for example, other imaging pixel signals, and can be affected by, for example, asymmetric pixels, microlens shift, and the placement of non-light gathering elements. Crosstalk may result in color shading.

For example, if a red, green, blue (RGB) Bayer pattern color filter array (CFA) is placed over imaging pixels of an imaging sensor to make the pixels sensitive to color, color shading can be defined as the change in the ratios of red to green, blue to green, or red to blue. A flat-field image with color shading may appear yellow on the left side of the image, while the right side appears blue. Color shading may be illuminant dependent, changing with the color of the light projected on the imaging sensor. Illuminant dependent color shading might not be significant in imaging devices with imaging sensors having larger pixels. However, illuminant dependent color shading is more pronounced in imaging devices with imaging sensors with smaller pixels. Accordingly, improved methods and apparatuses are needed to correct illuminant dependent color shading.

### BRIEF DESCRIPTION OF THE DRAWINGS

FIG. 1 illustrates a top view of a CMOS pixel array.

FIG. 2A illustrates a top view of a 2×2 pixel group.

FIG. 2B illustrates a top view of a 4×4 pixel group.

FIG. 3A illustrates a 4×4 pixel group having a red, green, blue (RGB) Bayer pattern color filter array (with Position 1 in bold print).

FIG. 3B illustrates a 4×4 pixel group having a red, green, blue (RGB) Bayer pattern color filter array (with Position 2 in bold print).

FIG. 3C illustrates a 4×4 pixel group having a red, green, blue (RGB) Bayer pattern color filter array (with Position 3 in bold print).

FIG. 3D illustrates a 4×4 pixel group having a red, green, blue (RGB) Bayer pattern color filter array (with Position 4 in bold print).

FIG. 4A illustrates a 4×4 pixel group having a red, green, blue (RGB) pattern color filter array in accordance with an embodiment (with Position 1 in bold print).

FIG. 4B illustrates a 4×4 pixel group having a red, green, blue (RGB) pattern color filter array in accordance with the FIG. 4A embodiment (with Position 2 in bold print).

FIG. 4C illustrates a 4×4 pixel group having a red, green, blue (RGB) pattern color filter array in accordance with the FIG. 4A embodiment (with Position 3 in bold print).

FIG. 4D illustrates a 4×4 pixel group having a red, green, blue (RGB) pattern color filter array in accordance with the FIG. 4A embodiment (with Position 4 in bold print).

FIG. 5A illustrates a 4×4 pixel group having a red, green, blue (RGB) pattern color filter array in accordance with an embodiment (with Position 1 in bold print).

FIG. 5B illustrates a 4×4 pixel group having a red, green, blue (RGB) pattern color filter array in accordance with the FIG. SA embodiment (with Position 2 in bold print).

FIG. 5C illustrates a 4×4 pixel group having a red, green, blue (RGB) pattern color filter array in accordance with the FIG. 5A embodiment (with Position 3 in bold print).

FIG. 5D illustrates a 4×4 pixel group having a red, green, blue (RGB) pattern color filter array in accordance with the FIG. SA embodiment (with Position 4 in bold print).

FIG. 6A illustrates a block diagram of system-on-a-chip imaging device constructed in accordance with an embodiment.

FIG. 6B illustrates an example of a sensor core used in the FIG. 6A device.

FIG. 7 shows a system embodiment incorporating at least one imaging device.

### DETAILED DESCRIPTION OF THE INVENTION

In the following detailed description, reference is made to the accompanying drawings which form a part hereof, and in which is shown by way of illustration specific embodiments that may be practiced. These embodiments are described in sufficient detail to enable those of ordinary skill in the art to make and use them, and it is to be understood that structural, logical, or procedural changes may be made to the specific embodiments disclosed. The embodiments herein are described in relation to a CMOS imaging device having a CMOS pixel array, however, the embodiments are not so limited and can be applied to other solid state imaging devices having a color filter pattern.

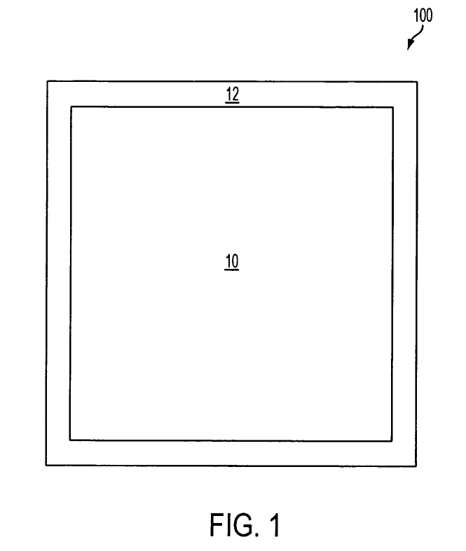

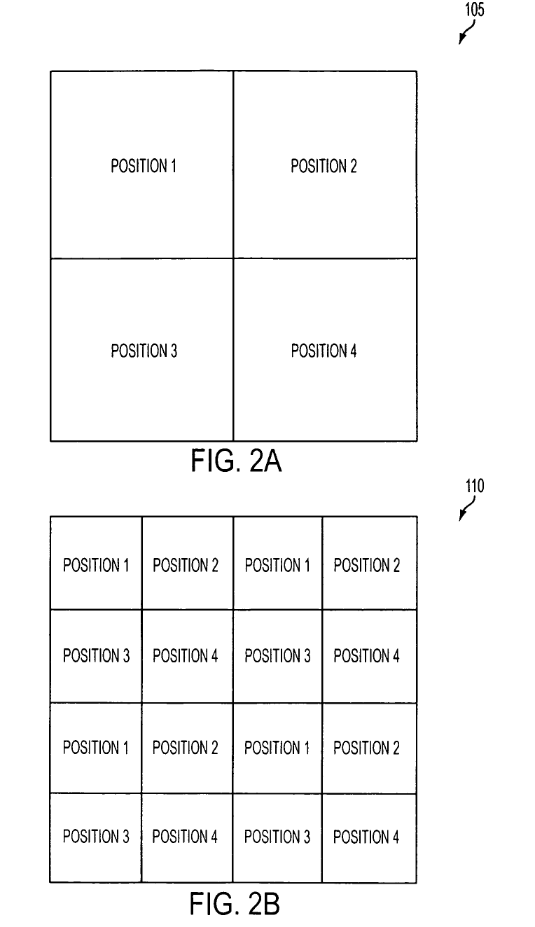

FIG. 1 shows an example CMOS pixel array 100 with an area 10 that contains rows and columns of imaging pixels and an area 12 that contains rows and columns of barrier pixels, which separate the imaging pixels from other pixels and circuits. The pixel array 100 may be comprised of a plurality of smaller pixel groups, such as, for example, the 2×2 pixel group 105 as shown in FIG. 2A. It should be appreciated that the plurality of smaller pixel groups can be comprised of any number of pixels and may, but need not, be symmetric. Each pixel of a pixel group, such as the 2×2 pixel group 105, may experience a unique crosstalk effect with respect to the other pixels in the group, due to, for example, photosensor asymmetry, micro lens shift in relation to the associated photosensor, placement of non-light gathering materials within the array, and pixels having a multi-way sharing of component parts (as described, for example, in published U.S. patent application Ser. No. 11/126,275, filed May 11, 2005, and having publication number 2006-0256221, where each pixel has a respective photosensor and a plurality of pixels share a readout circuit). Each pixel of the pixel group 105 can be referred to as having a unique pixel position. For example, as shown in FIG. 2A, the 2×2 pixel group 105 will have four pixel positions: Position 1, Position 2, Position 3, and Position 4.

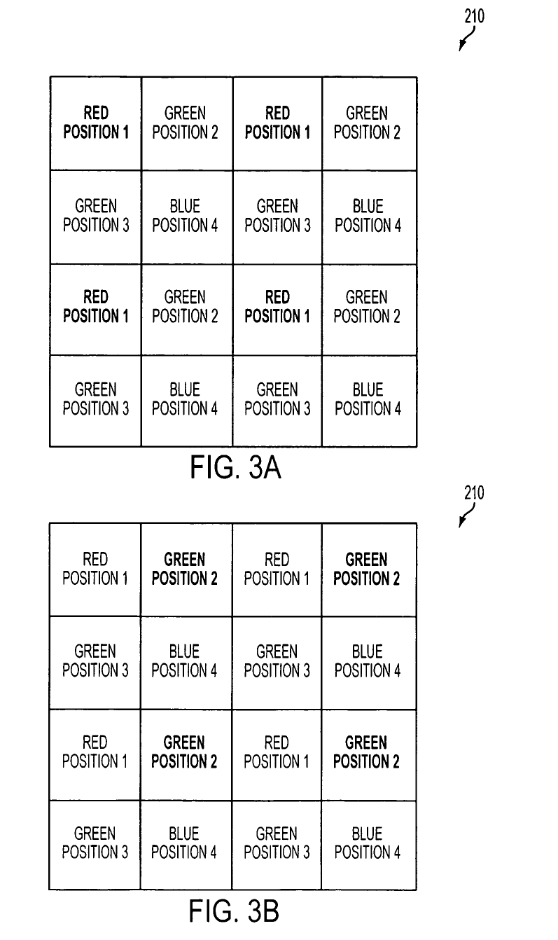

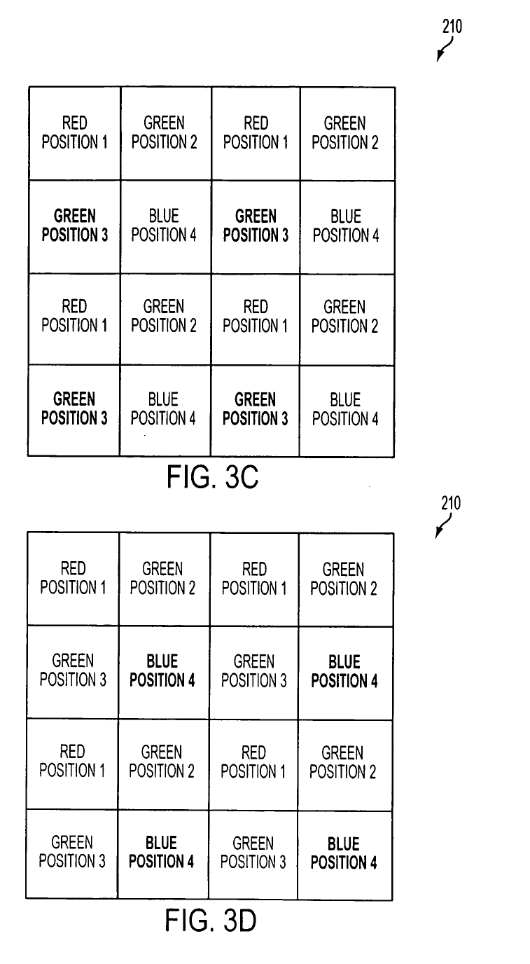

The pixel array 100 (FIG. 1) may have a color filter array (CFA) (not shown) over the imaging pixels in area 10 to make the pixels sensitive to color. One known color filter array is a red, green, blue (RGB) Bayer pattern color filter array in which every 2×2 group of pixels comprises one red pixel, two green pixels, and one blue pixel. Due to the repeating pattern of the 2×2 Bayer color filter array, the same color filter (e.g., red, green, blue) is always paired with the same position (e.g., Positions 1-4, FIG. 2A). For example, as shown in FIGS. 3A-3D, which illustrate a 4×4 group 210 having a Bayer pattern color filter array over four 2×2 pixel groups, Position 1 is always a red pixel (FIG. 3A, in bold print); Position 2 is always a green pixel (FIG. 3B, in bold print); Position 3 is always a green pixel (FIG. 3C, in bold print); and Position 4 is always a blue pixel (FIG. 3D, in bold print). Because the same color is always used for the same pixel position, each color pixel experiences a unique crosstalk effect. It should be appreciated that this is true even if the two green pixels are processed separately as greenblue (green pixels in the same row as blue pixels) and greenred (green pixels in the same row as red pixels) because Position 2 is always a greenred pixel (FIG. 3B) and Position 3 is always a greenblue pixel (FIG. 3C). Accordingly, an illuminant dependent, low frequency color shading may result in digital images created by an imaging device using an imaging sensor comprised of pixels associated with a Bayer pattern color filter array, particularly in a four-way shared 2×2 pixel group where the pixels in Positions 1-4 each have a unique photosensor area due to the sharing architecture. Therefore, it is desirable to distribute color filters in such a way that each pixel position is paired with each color, thereby reducing illuminant dependent color shading.

To distribute the crosstalk of each position, a group of pixels must be selected that is equal in size to the number of pixel positions (e.g., 4) multiplied by the number of pixels required to maintain a desired color ratio (e.g., 4—one red, two greens, and one blue). For example, FIG. 2B shows a 4×4 pixel group 110 comprised of four 2×2 groups 105 (FIG. 2A). If each pixel position (e.g., Positions 1-4, FIG. 2B) maintains the color ratio (e.g., one red, two greens, and one blue), the crosstalk of each pixel position will be distributed across the colors. Such a position distributed color filter array pattern reduces the low frequency, illuminant dependant color shading problem described above. The position distributed color filter array pattern introduces a high frequency luminance artifact, however, the newly introduced artifact is local to the selected group (e.g., 4×4 group of FIG. 2B) and, therefore, repeats predictably and can be corrected during or after demosaicing.

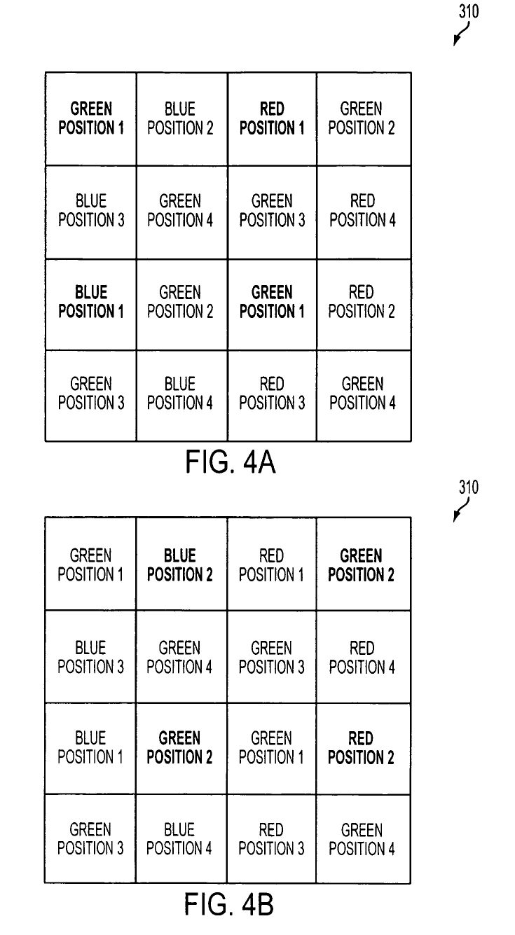

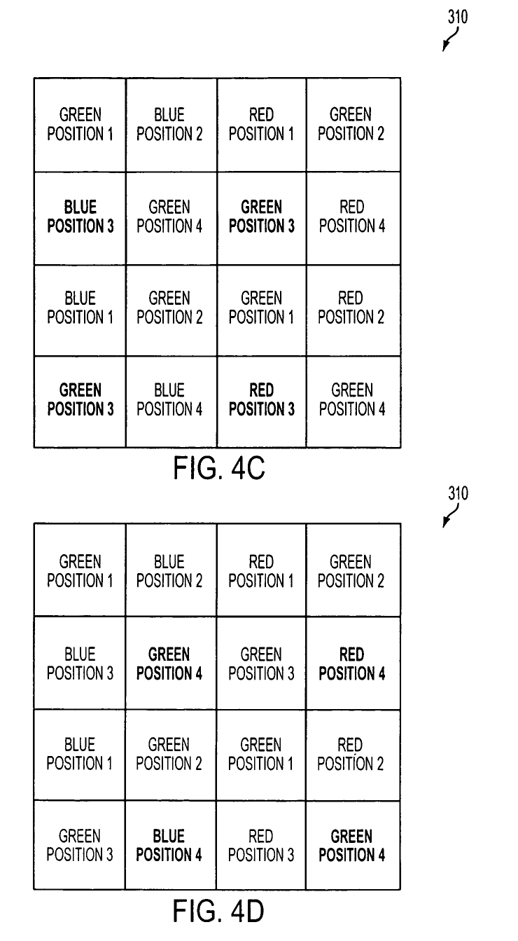

One embodiment of the new color filter array is shown in FIGS. 4A-4D. FIG. 4A shows Position 1 (bold) with one red pixel, one blue pixel, and two green pixels in a 4×4 pixel group 310. Similarly, FIGS. 4B-4D highlight Positions 2-4 (bold) respectively, each position having one red pixel, one blue pixel, and two green pixels in the 4×4 group 310. The 4×4 array 310 shown by FIGS. 4A-4D maintains the same overall ratio of red, green, and blue pixels as the 4×4 Bayer color filter array 210 shown in FIGS. 3A-3D. However, unlike the 4×4 Bayer color filter array 210 shown in FIGS. 3A-3D, the 4×4 array 310 shown by FIGS. 4A-4D also maintains the same ratio of red, green, and blue pixels for each position (Position 1-Position 4). Color filter array 310 has a good distribution of green pixels; there is even spacing between greens of the same position (i.e., Green Position 1, Green Position 2, Green Position 3, and Green Position 4).

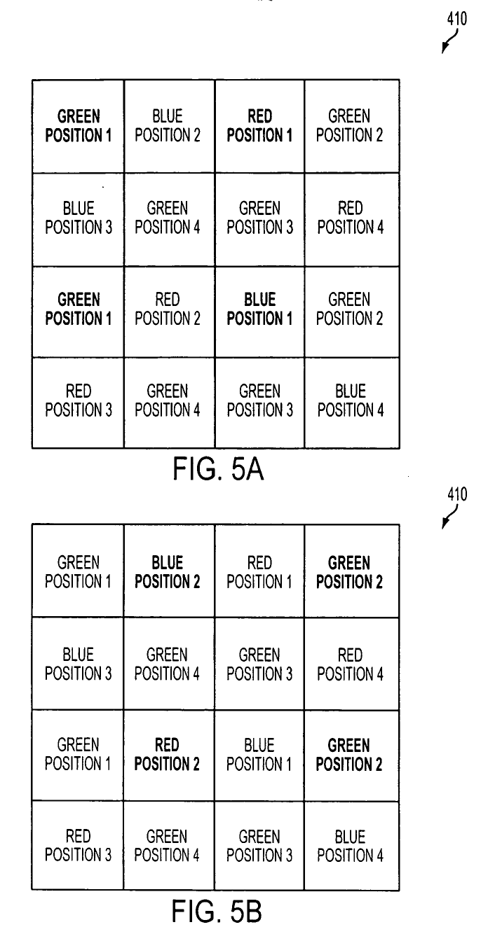

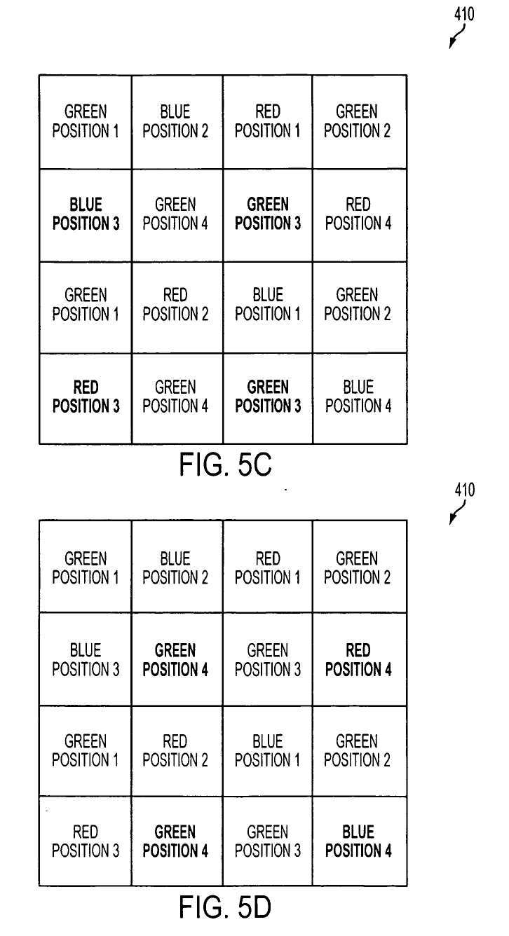

Another embodiment of the new color filter array is shown in FIGS. 5A-5D. FIG. 5A shows Position 1 (bold) with one red pixel, one blue pixel, and two green pixels in a 4×4 pixel group 410. Similarly, FIGS. 5B-5D highlight Positions 2-4 (bold) respectively, each having one red pixel, one blue pixel, and two green pixels in the 4×4 group 410. The 4×4 array 410 shown by FIGS. 5A-5D maintains the same overall ratio of red, green, and blue pixels as the 4×4 Bayer color filter array 210 shown in FIGS. 3A-3D. However, unlike the 4×4 Bayer color filter array 210 shown in FIGS. 3A-3D, the 4×4 array 410 shown by FIGS. 5A-5D also maintains the same ratio of red, green, and blue pixels for each position (Position 1-Position 4). In color filter array 410, the two greens of the same position (i.e., Green Position 1, Green Position 2, Green Position 3, and Green Position 4) are always in the same column, which may make the high frequency luminance artifact more difficult to remove than in color filter array 310 (FIGS. 4A-4D). However, the red and blue pixels are fairly evenly distributed in color filter array 410, which may be advantageous over color filter array 310 (FIGS. 4A-4D).

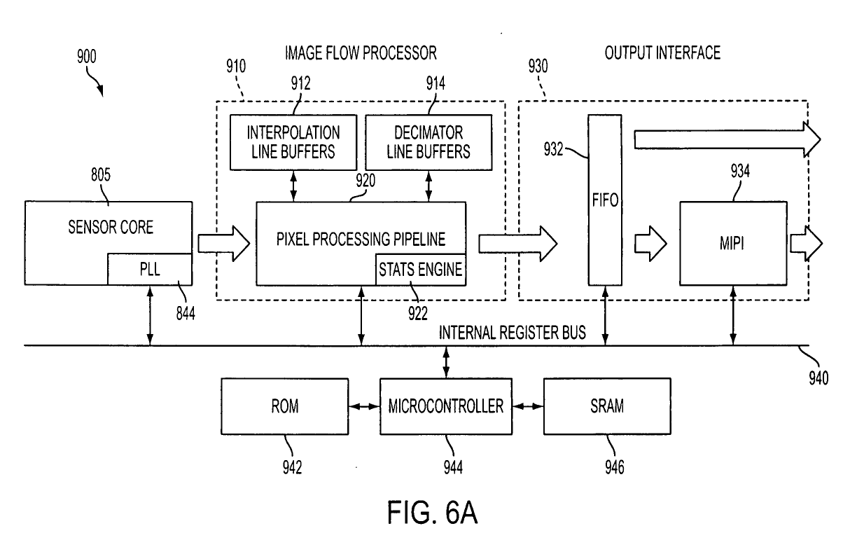

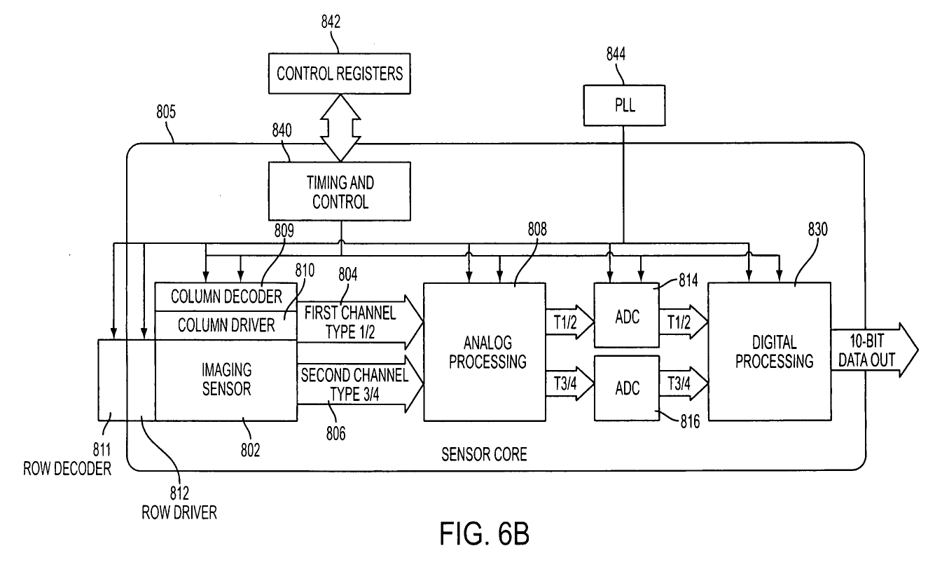

FIG. 6A illustrates a block diagram of an exemplary system-on-a-chip (SOC) CMOS imaging device 900 constructed in accordance with an embodiment. The imaging device 900 comprises a sensor core 805 that communicates with an image flow processor 910 that is also connected to an output interface 930. A phase locked loop (PLL) 844 is used as a clock for the sensor core 805. The image flow processor 910, which is responsible for image and color processing, includes interpolation line buffers 912, decimator line buffers 914, and a color pipeline 920. The color pipeline 920 includes, among other things, a statistics engine 922. The output interface 930 includes an output first-in-first-out (FIFO) parallel output 932 and a serial Mobile Industry Processing Interface (MIPI) output 934. The user can select either a serial output or a parallel output by setting registers within the chip. An internal register bus 940 connects read only memory (ROM) 942, a microcontroller 944 and a static random access memory (SRAM) 946 to the sensor core 805, image flow processor 910 and the output interface 930.

FIG. 6B illustrates a sensor core 805 used in the FIG. 6A imaging device 900. The sensor core 805 includes an imaging sensor 802, having a color filter array constructed in accordance with one of the embodiments described above, which is connected to analog processing circuitry 808 by a first channel 804 and a second channel 806. Although only two channels 804, 806 are illustrated, there are effectively twelve channels, Position 1 Red, Position 1 Green, Position 1 Blue, Position 2 Red, Position 2 Green, Position 2 Blue, Position 3 Red, Position 3 Green, Position 3 Blue, Position 4 Red, Position 4 Green, and Position 4 Blue. The signal values for six of the color channels, for example all of the Position 1 and Position 2 signals (Position 1/2) (e.g., Position 1 Red, Position 1 Green, Position 1 Blue, Position 2 Red, Position 2 Green, and Position 2 Blue) are readout at different times (using first channel 804) and the other six color channels, for example all of the Position 3 and Position 4 signals (Position 3/4) (e.g., Position 3 Red, Position 3 Green, Position 3 Blue, Position 4 Red, Position 4 Green, and Position 4 Blue) signal values are readout at different times (using second channel 806). It should be appreciated that first channel 804 and second channel 806 are simply illustrative of one readout architecture and that other readout architectures may be utilized. The analog processing circuitry 808 outputs processed signal values (Position 1/2) to a first analog-to-digital converter (ADC) 814 and processed signal values (Position 3/4) corresponding to the second channel 806 to a second analog-to-digital converter 816. The outputs of the two analog-to-digital converters 814, 816 are sent to a digital processor 830.

Connected to, or as part of, the imaging sensor 802 are row and column decoders 811, 809 and row and column driver circuitry 812, 810 that are controlled by a timing and control circuit 840. The timing and control circuit 840 uses control registers 842 to determine how the imaging sensor 802 and other components are controlled. As set forth above, the PLL 844 serves as a clock for the components in the core 805.

The imaging sensor 802 comprises a plurality of pixel circuits arranged in a predetermined number of columns and rows. Imaging sensor 802 may be configured with a color filter array in accordance with the embodiments described herein. In operation, the pixel circuits of each row in imaging sensor 802 are all turned on at the same time by a row select line and the pixel circuits of each column are selectively output onto column output lines by a column select line. A plurality of row and column lines are provided for the entire imaging sensor 802. The row lines are selectively activated by row driver circuitry 812 in response to the row address decoder 811 and the column select lines are selectively activated by a column driver 810 in response to the column address decoder 809. Thus, a row and column address is provided for each pixel circuit. The timing and control circuit 840 controls the address decoders 811, 809 for selecting the appropriate row and column lines for pixel readout and the row and column driver circuitry 812, 810, which apply driving voltage to the drive transistors of the selected row and column lines.

Each column contains sampling capacitors and switches in the analog processing circuit 808 that read a pixel reset signal Vrst and a pixel image signal Vsig for selected pixel circuits. Because the core 805 uses first channel 804 and a separate second channel 806, circuitry 808 will have the capacity to store Vrst and Vsig signals for Position 1 Red, Position 1 Green, Position 1 Blue, Position 2 Red, Position 2 Green, Position 2 Blue, Position 3 Red, Position 3 Green, Position 3 Blue, Position 4 Red, Position 4 Green, and Position 4 Blue pixel signals. A differential signal (Vrst-Vsig) is produced by differential amplifiers contained in the circuitry 808 for each pixel. Thus, the signals Position 1/2, Position 3/4 are differential signals that are then digitized by a respective analog-to-digital converter 814, 816. The analog-to-digital converters 814, 816 supply digitized Position 1/2, Position 3/4 pixel signals to the digital processor 830, which forms a digital image output (e.g., a 10-bit digital output). The digital processor 830 performs pixel processing operations. The output is sent to the image flow processor 910 (FIG. 6A).

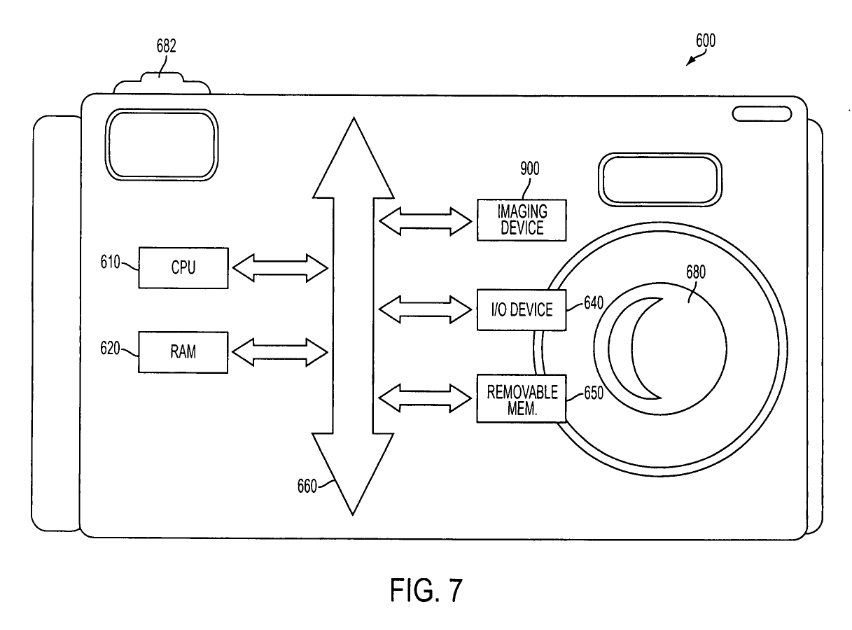

Although the sensor core 805 has been described with reference to use with a CMOS imaging sensor, this is merely one example sensor core that may be used. Embodiments of the invention may also be used with other sensor cores having a different readout architecture. While the imaging device 900 (FIG. 6A) has been shown as a system-on-a-chip, it should be appreciated that the embodiments are not so limited. Other imaging devices, such as, for example, a stand-alone sensor core 805 coupled to a separate signal processing chip could be used in accordance with the embodiments. Additionally, imaging data from the imaging sensor 802 (FIG. 6B) can be output from the data output (FIG. 6B) and stored and processed elsewhere, for example, in a system as described in relation to FIG. 7 or in a stand-alone image processing system.

FIG. 7 shows a typical system 600, such as, for example, a camera system, including one incorporated into a camera phone or other electronic device. The system 600 is an example of a system having digital circuits that could include imaging devices 900. Without being limiting, such a system could include a computer system, camera system, scanner, machine vision, vehicle navigation system, video phone, surveillance system, auto focus system, star tracker system, motion detection system, image stabilization system, and other systems employing an imaging device 900.

System 600, for example, a camera system, includes a lens 680 for focusing an image on the imaging device 900 when a shutter release button 682 is pressed. System 600 generally comprises a central processing unit (CPU) 610, such as a microprocessor that controls camera functions and image flow, and communicates with an input/output (I/O) device 640 over a bus 660. The imaging device 900 also communicates with the CPU 610 over the bus 660. The system 600 also includes random access memory (RAM) 620, and can include removable memory 650, such as flash memory, which also communicates with the CPU 610 over the bus 660. The imaging device 900 may be combined with the CPU 610, with or without memory storage on a single integrated circuit, such as, for example, a system-on-a-chip, or on a different chip than the CPU 610. As described above, data from the imaging sensor 802 (FIG. 6B) can be output from the imaging device 900 and stored, for example in the random access memory 620 or the CPU 610. Processing can then be performed on the stored data by the CPU 610, or can be sent outside the camera and stored and operated on by a stand-alone processor, e.g., a computer, external to system 600.

Some of the advantages of the color filter array pattern methods and apparatuses disclosed herein include reducing illuminant dependent crosstalk in image signals thereby improving the image quality for imaging sensors with small sized pixels.

While the embodiments have been described in detail in connection with preferred embodiments known at the time, it should be readily understood that the claimed invention is not limited to the disclosed embodiments. Rather, the embodiments can be modified to incorporate any number of variations, alterations, substitutions, or equivalent arrangements not heretofore described. For example, while the embodiments are described in connection with a CMOS imaging sensor, they can be practiced with other types of imaging sensors. Additionally any number of color channels may be used, rather than twelve, for example, and they may comprise additional or different positions than Positions 1-4 or additional or different colors/channels than red, green, and blue, such as e.g., cyan, magenta, yellow (CMY); cyan, magenta, yellow, black (CMYK); or red, green, blue, indigo (RGBI).

What is claimed as new and desired to be protected by Letters Patent of the United States is:

1. An image sensor comprising:
a pixel array comprising a plurality of pixels arranged in rows and columns and further arranged into a plurality of pixel groups, each pixel group comprising a plurality of pixel subgroups, each pixel subgroup having a plurality of pixel positions; and
an array of color filters, each filter having a color selected from a plurality of colors, the filters having a predetermined ratio of each color relative to each other color in a pixel group and wherein the ratio is maintained for each pixel position in the group.

2. The image sensor of claim 1, wherein there are four pixel positions.

3. The image sensor of claim 1, wherein the pixels have a multi-way sharing of component parts.

4. The image sensor of claim 1, wherein the pixels have a 4-way sharing of component parts.

5. The image sensor of claim 1, wherein there are three colors.

6. The image sensor of claim 1, wherein the colors are red, green, and blue.

7. The image sensor of claim 1, wherein the ratio comprises one red to two green to one blue.

8. The image sensor of claim 1, wherein each group comprises a number of pixels equal to the number of pixel positions multiplied by the number of filters required to maintain the ratio

9. The image sensor of claim 1, wherein each group comprises:
a first row comprising a pixel of a first position having an associated green filter adjacent a pixel of a second position having an associated blue filter adjacent a pixel of the first position having an associated red filter adjacent a pixel of the second position having an associated green filter;
a second row comprising a pixel of a third position having an associated blue filter adjacent a pixel of a fourth position having an associated green filter adjacent a pixel of the third position having an associated green filter adjacent a pixel of the fourth position having an associated red filter;
a third row comprising a pixel of the first position having an associated blue filter adjacent a pixel of the second position having an associated green filter adjacent a pixel of the first position having an associated green filter adjacent a pixel of the second position having an associated red filter; and
a fourth row comprising a pixel of the third position having an associated green filter adjacent a pixel of the fourth position having an associated blue filter adjacent a pixel of the third position having an associated red filter adjacent a pixel of the fourth position having an associated green filter.

10. The image sensor of claim 1, wherein each group comprises:
a first row comprising a pixel of a first position having an associated green filter adjacent a pixel of a second position having an associated blue filter adjacent a pixel of the first position having an associated red filter adjacent a pixel of the second position having an associated green filter;
a second row comprising a pixel of a third position having an associated blue filter adjacent a pixel of a fourth position having an associated green filter adjacent a pixel of the third position having an associated green filter adjacent a pixel of the fourth position having an associated red filter;
a third row comprising a pixel of the first position having an associated green filter adjacent a pixel of the second position having an associated red filter adjacent a pixel of the first position having an associated blue filter adjacent a pixel of the second position having an associated green filter; and
a fourth row comprising a pixel of the third position having an associated red filter adjacent a pixel of the fourth position having an associated green filter adjacent a pixel of the third position having an associated green filter adjacent a pixel of the fourth position having an associated blue filter.

11. An image sensor having pixels arranged in an array having columns and rows and further arranged into at least one pixel group, the at least one group comprising:
a first row comprising a pixel having an associated green filter adjacent a pixel having an associated blue filter adjacent a pixel having an associated red filter adjacent a pixel having an associated green filter;
a second row comprising a pixel having an associated blue filter adjacent a pixel having an associated green filter adjacent a pixel having an associated green filter adjacent a pixel having an associated red filter;
a third row comprising a pixel having an associated blue filter adjacent a pixel having an associated green filter adjacent a pixel having an associated green filter adjacent a pixel having an associated red filter; and
a fourth row comprising a pixel having an associated green filter adjacent a pixel having an associated blue filter adjacent a pixel having an associated red filter adjacent a pixel having an associated green filter.

12. The image sensor of claim 11, wherein the pixels in the at least one group have a multi-way sharing of component parts.

13. The image sensor of claim 11, wherein the pixels in the at least one group have a 4-way sharing of component parts.

14. The image sensor of claim 11, further comprising a plurality of pixel groups.

15. An image sensor having pixels arranged in an array having columns and rows and further arranged into at least one pixel group, the at least one group comprising:
a first row comprising a pixel having an associated green filter adjacent a pixel having an associated blue filter adjacent a pixel having an associated red filter adjacent a pixel having an associated green filter;
a second row comprising a pixel having an associated blue filter adjacent a pixel having an associated green filter adjacent a pixel having an associated green filter adjacent a pixel having an associated red filter;
a third row comprising a pixel having an associated green filter adjacent a pixel having an associated red filter adjacent a pixel having an associated blue filter adjacent a pixel having an associated green filter; and
a fourth row comprising a pixel having an associated red filter adjacent a pixel having an associated green filter adjacent a pixel having an associated green filter adjacent a pixel having an associated blue filter.

16. The image sensor of claim 15, wherein the pixels in the at least one group have a multi-way sharing of component parts.

17. The image sensor of claim 15, wherein the pixels in the at least one group have a 4-way sharing of component parts.

18. The image sensor of claim 15, further comprising a plurality of pixel groups.
